(19) United States
(12) Patent Application Publication
(10) Pub. No.: US 2008/0098957 A1
(43) Pub. Date: May 1, 2008

(54) Deposition apparatus and method

(76) Inventors: Seung-Yoon Ryu, Suwon-si (KR); Hyun-Lae Cho, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/978,637

(22) Filed: Oct. 30, 2007

(30) Foreign Application Priority Data
Oct. 30, 2006 (KR) 10-2006-0105852

(51) Int. Cl. C23C 16/00

(52) U.S. Cl. 118/712

(57) ABSTRACT

A deposition apparatus includes at least one deposition chamber having a source and a substrate holder, the source being configured to deposit a deposition material on a substrate on the substrate holder, a measurement chamber electrically connected to the deposition chamber, the measurement chamber configured to measure in real time a thickness of the deposition material on the substrate, and at least one layer thickness controller in contact with the deposition chamber, the layer thickness controller being configured to control deposition of the deposition material on the substrate to a predetermined thickness in real time.

### BACKGROUND OF THE INVENTION

1. Field of the Invention

Embodiments of the present invention relate to a deposition apparatus and a method for depositing a layer on a substrate. More particularly, embodiments of the present invention relate to a deposition apparatus and a method providing real time thickness measurement of a deposited layer and adjustment thereof.

2. Description of the Related Art

In general, an electroluminescent (EL) display device, e.g., an organic light emitting display device, refers to a display device capable of forming images via a combination of electrons and holes in light emitting layers. A conventional EL display device, e.g., active or passive matrix type, may include a substrate and at least one light emitting layer between two electrodes. Accordingly, voltage may be applied to the electrodes to combine electrons and holes in the light emitting layer, thereby forming excitons to generate visible light upon changing from an excited state to a ground state. The visible light may be emitted either toward the substrate, i.e., bottom emission type display, or away from the substrate, i.e., a top emission type display.

A conventional light emitting layer may be formed on the substrate by a deposition apparatus, e.g., using a thermal deposition technique. More specifically, a conventional deposition apparatus may include a chamber with an evaporation source for evaporating a deposition material, a substrate holder, and a sensor. The sensor may determine an amount of the evaporated deposition material in the chamber in order to evaluate an amount of material deposited on a substrate in the substrate holder.

However, since the sensor may determine the amount of the evaporated material in the entire chamber, evaluation of the amount of material deposited on the substrate is indirect, and therefore, may be inaccurate. Accordingly, there exists a need for an apparatus capable of providing an accurate measurement of a thickness of a layer deposited on the substrate.

### SUMMARY OF THE INVENTION

The present invention is therefore directed to a deposition apparatus and a method for depositing a layer therewith, which substantially overcome one or more of the disadvantages of the related art.

It is therefore a feature of an embodiment of the present invention to provide a deposition apparatus capable of directly measuring and adjusting a thickness of a deposited layer on a substrate in real time.

It is another feature of an embodiment of the present invention to provide a method for depositing a layer having a desired predetermined thickness on a substrate in real time.

At least one of the above and other features and advantages of the present invention may be realized by providing a deposition apparatus including at least one deposition chamber having a source and a substrate holder, the source being configured to deposit a deposition material on a substrate on the substrate holder, a measurement chamber electrically connected to the deposition chamber, the measurement chamber configured to measure in real time a thickness of the deposition material on the substrate, and at least one layer thickness controller in contact with the deposition chamber, the layer thickness controller being configured to control deposition of the deposition material on the substrate to a predetermined thickness in real time.

The layer thickness controller may be electrically connected to the measurement chamber to receive the measured thickness, and may be configured to control thickness adjustment thereof in accordance with the predetermined thickness. The layer thickness controller may include a shutter positioned between the evaporation source and the substrate holder. The layer thickness controller may be configured to open or close the shutter in response to a comparison between the predetermined thickness and the measured thickness.

The measurement chamber may further include a lower plate with first and second optical transmission holes therethrough, a layer thickness monitoring unit configured to direct light toward the substrate, and a detector unit configured to receive light reflected from the substrate. The detector unit may be configured to determine the measured thickness and to transmit the measured thickness to the layer thickness controller. The detector unit may include an ellipsometer. The layer thickness monitoring unit may be under the lower plate, and may be configured to transmit light through the first optical transmission hole, and the detector unit may be configured to receive light through the second optical transmission hole. The optical transmission holes may include glass. The deposition apparatus may include a plurality of deposition chambers and a plurality of layer thickness controllers, each deposition chamber being electrically connected to the measurement chamber via a respective layer thickness controller.

At least one of the above and other features and advantages of the present invention may be realized by providing a deposition method, including depositing a deposition material on a predetermined region of a substrate in a deposition chamber, measuring in real time a thickness of the deposition material on the substrate in a measurement chamber, comparing the measured thickness to a reference value to determine a tooling factor, and controlling deposition of the deposition material on the substrate in real time with respect to the tooling factor by a layer thickness controller.

Controlling the thickness of the deposition material may include adjusting a flow rate and/or amount of the deposition material in the deposition chamber. Controlling the flow rate and/or amount of the deposition material in the deposition chamber may include opening and closing a shutter by the layer thickness controller.

Depositing the deposition material may include a bottom-up rotation deposition technique, a bottom-up deposition technique, a top-down deposition technique, and/or a vertical deposition technique. Depositing the deposition material may include depositing organic material. Depositing the deposition material on a predetermined region of the substrate may include simultaneous deposition on a panel portion of the substrate and on a panel peripheral portion of the substrate. Measuring the thickness of the deposition material may include measuring the thickness in one or more of the panel peripheral portion of the substrate and/or the panel portion of the substrate.

Measuring the thickness of the deposition material may include moving the substrate from the deposition chamber to the measurement chamber. Measuring the thickness of the deposition material may include measurement by an optical method, a mechanical method, and/or a microscopic method. Measuring the thickness of the deposition material includes measurement by an optical method, the optical method including measurement via an ellipsometer and/or a reflectometer.

### BRIEF DESCRIPTION OF THE DRAWINGS

The above and other features and advantages of the present invention will become more apparent to those of ordinary skill in the art by describing in detail embodiments thereof with reference to the attached drawings, in which:

FIG. 1 illustrates a block diagram of a deposition apparatus according to an embodiment of the present invention;

FIG. 2 illustrates a schematic plan view of a material layer sample on a substrate according to an embodiment of the present invention;

FIG. 3 illustrates a cross-sectional view of a deposition chamber in a deposition apparatus according to an embodiment of the present invention;

FIG. 4 illustrates a schematic perspective view of a measuring chamber in a deposition apparatus according to an embodiment of the present invention;

FIG. 5 illustrates a schematic plan view of a substrate of an electroluminescent (EL) display device having a layer formed according to an embodiment of the present invention;

FIG. 6 illustrates a schematic plan view of a single pixel unit on the substrate of FIG. 5;

FIG. 7A illustrates a schematic cross-sectional view of a pixel region on the substrate of FIG. 5;

FIG. 7B illustrates a cross-sectional view along line A-A′ in FIG. 6 and an enlarged view of area B of FIG. 7A; and

FIG. 7C illustrates a schematic cross-sectional view of a light emitting layer in the EL of FIGS. 5-7B.

### DETAILED DESCRIPTION OF THE INVENTION

Korean Patent Application No. 10-2006-0105852, filed on Oct. 30, 2006, in the Korean Intellectual Property Office, and entitled: “Deposition Apparatus and Method,” is incorporated by reference herein in its entirety.

Embodiments of the present invention will now be described more fully hereinafter with reference to the accompanying drawings, in which exemplary embodiments of the invention are illustrated. Aspect of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, or one or more intervening layers may also be present. In addition, it will also be understood that when a layer is referred to as being “between” two layers, it can be the only layer between the two layers, or one or more intervening layers may also be present. It will be further understood that terminology such as “layer,” “deposited layer,” “material layer,” and so forth is used interchangeably. Like reference numerals refer to like elements throughout.

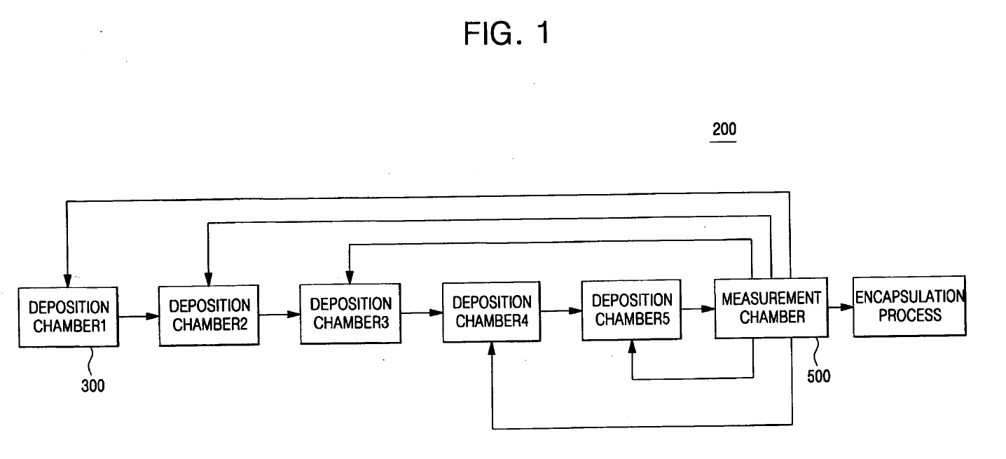

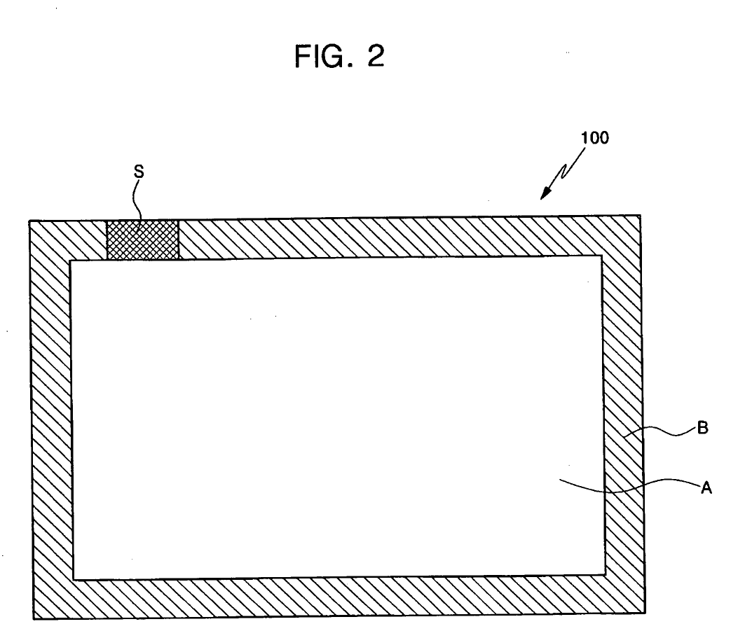

An exemplary embodiment of a deposition apparatus according to the present invention will now be described more fully with reference to FIGS. 1-4. As illustrated in FIG. 1, a deposition apparatus 200 may include at least one deposition chamber 300 and a measurement chamber 500. Accordingly, a substrate (not shown) may be positioned in the deposition chamber 300, so that a material layer may be deposited thereon. The material layer may include a film layer (not shown) deposited on a first predetermined area A of the substrate, e.g., a central region, to form a functional film, e.g., a light emitting layer. Further, the material layer may include a sample material layer S deposited in a second predetermined area B of the substrate, e.g., a peripheral region, as illustrated in FIG. 2. The film layer and the sample material layer S of the material layer may be deposited on the substrate simultaneously, thereby having a substantially identical thickness.

The number of the deposition chambers 300 may depend on a desired number of layers on a single substrate, so that each layer may be deposited in a separate deposition chamber 300. For example, a first layer may be deposited in a first deposition chamber 300, a second layer may be deposited in a second deposition chamber 300, and so forth. Each layer may include a film layer on the first predetermined area of the substrate and a corresponding material layer sample on the second predetermined area of the substrate. It should be noted that when a plurality of film layers are formed to be stacked on top of each other, the corresponding material layer samples may be coplanar, e.g., each material layer sample may be in direct communication with the substrate.

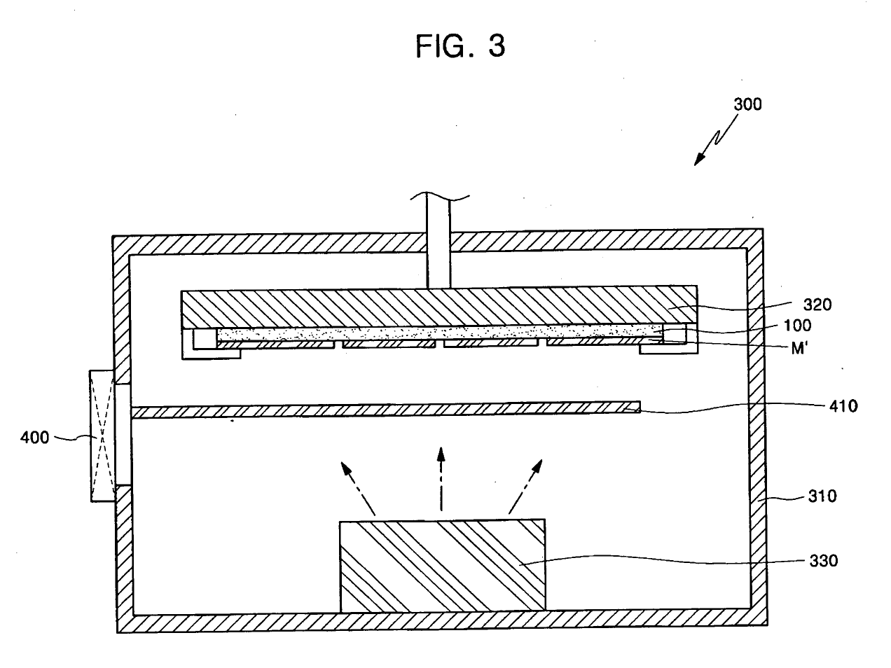

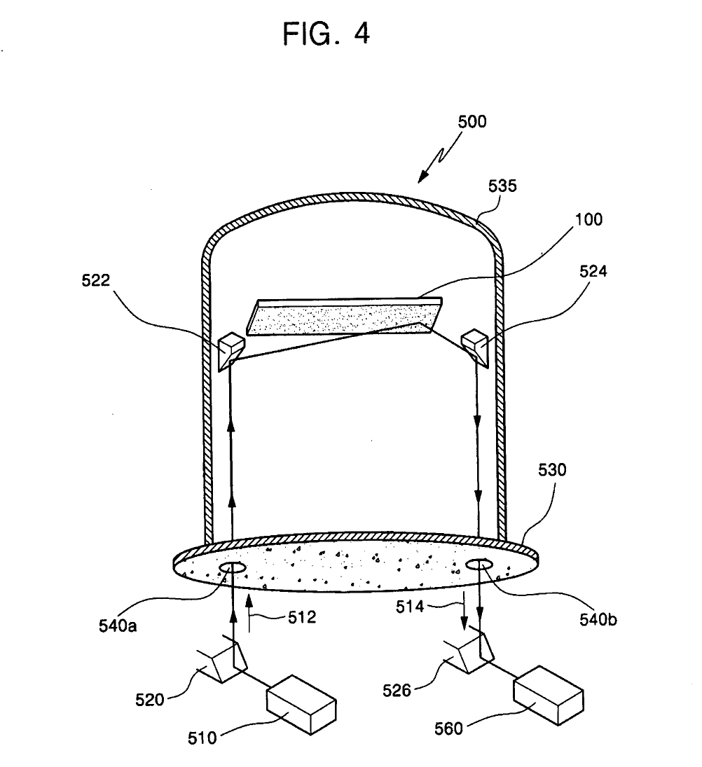

Next, the substrate may be transferred to the measurement chamber 500 to measure a thickness of the material layer deposited thereon. The thickness of the deposited material may be measured by determining a thickness of the material layer sample. When a plurality of film layers is formed, each of the corresponding material layer samples may be measured independently of each other. If the thickness of the measured material layer sample is insufficient, the substrate may be transferred back to the deposition chamber 300 for thickness adjustment of the entire deposited material layer, as will be discussed in more detail below with respect to FIGS. 3-4. On the other hand, if the thickness of the layer is sufficient, the substrate may be transferred for further processing, e.g., an encapsulation process.

The deposition and measurement chambers 300 and 500 may be vacuum chambers, and may be electrically connected to each other. Accordingly, the substrate may be transferred between the deposition chambers 300 for layer deposition, and the substrate may be transferred between each deposition chamber 300 and the measurement chamber 500 for measurement of each deposited layer prior to transfer to a subsequent deposition chamber 300.

The deposition chamber 300, as illustrated in FIG. 3, may include a substrate holder 320, an evaporation source 330, and a layer thickness controller 400 with a shutter 410 in a vacuum housing 310. The vacuum housing 310 may be any suitable container capable of being pressure-controlled and of maintaining a vacuum atmosphere therein.

The substrate holder 320 of the deposition chamber 300 may be positioned at an upper portion of the vacuum housing 310, e.g., in parallel to a bottom thereof. Accordingly, a substrate 100 may be attached to the substrate holder 320, so that a surface of the substrate 100 to be coated may face a lower portion of the vacuum chamber 310. A shadow mask M′ may be attached to the substrate 100, i.e., the shadow mask M′ may be positioned between the substrate 100 and the lower portion of the vacuum chamber 310, to facilitate deposition of material in the first and/or second predetermined regions A and B of the substrate 100. In other words, the shadow mask M′ may be used to deposit a film layer in the first predetermined region A of the substrate 100 and a material layer sample in the second predetermined region B of the substrate 100.

The evaporation source 330 of the deposition chamber 300, as further illustrated in FIG. 3, may be disposed in the lower portion of the vacuum housing 310, so that material released therefrom may be directed in an upward direction toward the substrate 100 in the substrate holder 320′. The evaporation source 330 may contain deposition material, e.g., organic material, and may provide sufficient heat to evaporate the deposition material, so that the evaporated deposition material may form a layer with a predetermined thickness on the substrate 100. The evaporation source 330 may be electrically connected to the measurement chamber 500, so that thickness of a deposited layer on the substrate 100 may be potentially adjusted by controlling flow rate and/or amount of the deposition material from the evaporation source 330.

The layer thickness controller 400 of the deposition chamber 300 may be formed in contact with the vacuum housing 310, e.g., along an external surface of a sidewall thereof, and may be electrically connected to the measurement chamber 500. Accordingly, the layer thickness controller 400 may receive a value from the measurement chamber 500 that represents a difference between a measured thickness of a layer deposited on the substrate 100 and a reference value, i.e., a desired predetermined thickness. The layer thickness controller 400 may adjust the thickness of the deposited material on the substrate 100 with respect to the received value, i.e., a differences between the measured and reference values. The value received by the layer thickness controller 400 from the measurement chamber 500 may be expressed in terms of a tooling factor, as will be explained in detail below with respect to FIG. 4.

The thickness of the deposited material on the substrate 100 may be adjusted by, e.g., adjustment of flow rate and/or amount of the deposition material via the evaporation source 330 and/or the shutter 410. If the measured thickness is below the reference thickness value, additional deposited material may be deposited on the substrate 100. If the measured thickness exceeds the reference thickness value, the deposited material may be deteriorated to achieve the desired thickness.

The shutter 410 layer thickness controller 400 may extend from the sidewall of the deposition chamber 300, i.e., from the layer thickness controller 400, across the vacuum housing 310, and may be electrically connected to the layer thickness controller 400, e.g., via a logic program. The shutter 410 may be positioned between the substrate holder 320 and the evaporation source 330, so that evaporated deposition material moving from the evaporation source 330 toward the substrate holder 320 may pass therethrough. The shutter 410 may be configured to responds to a signal generated by the layer thickness controller 400 by opening or closing to a predetermined degree. In other words, opening and/or closing of the shutter 410 may control a flow amount of the deposition material moving through the shutter 410, thereby controlling the amount of deposition material deposited on the substrate 100, i.e., a thickness thereof.

The deposition material may be deposited on the substrate 100 via, e.g., a bottom-up rotation deposition, a bottom-up deposition, a top-down deposition, a vertical deposition, and so forth. The bottom-up rotation deposition may include rotating a substrate, while forming a layer thereon using a Knudsen or an effusion-type deposition source. The bottom-up deposition may include a horizontal movement of a substrate, while forming a layer thereon using a moving evaporation source under the substrate via, e.g., linear effusion or linear nozzle spraying. The top-down deposition may include a horizontal movement of a substrate, while spraying a deposition material in a downward direction through a linear or a planar nozzle of an evaporation source. The vertical deposition may include a fixed vertical linear evaporation source, e.g., an effusion type or a nozzle type, depositing a deposition material on a moving substrate. In this respect, it is noted that a horizontal direction refers to a direction parallel to a surface supporting the evaporation source. Once the deposition material forms a layer on the substrate 100 in the deposition chamber 300, the substrate 100 may be transferred from the deposition chamber 300 into the measurement chamber 500.

The measurement chamber 500, as illustrated in FIG. 4, may include a housing 535, a lower plate 530 having first and second optical transmission holes 540a and 540b, and a plurality of prisms. The housing 535 may provide upper and side surfaces of the measurement chamber 500, and may be fixed to the lower plate 530. The housing 535 and lower plate 530 may form a sealed space having a vacuum atmosphere therein, e.g., provided by a vacuum pump (not shown), so the substrate 100 may be positioned inside the measurement chamber 500. The first and second optical transmission holes 540a and 540b may be formed, e.g., of glass, in order to maintain a vacuum condition in the measurement chamber 500 and to transmit light.

As further illustrated in FIG. 4, an incident light 512 from a layer thickness monitoring unit 510 may be reflected by a first prism 520 into the measurement chamber 500 via the first optical transmission hole 540a to be reflected by a second prism 522 to be incident on a lower surface of the substrate 100, i.e., a surface facing the lower plate 530. The incident light 512 may be reflected from the substrate 100 at a predetermined angle with respect to a refractive index and a thickness of the deposition material to form a monitor light 514. A third prism 524 may reflect the monitor light 514 through the second optical transmission hole 540b, and a fourth prism 526 may reflect the monitor light 514 to a detector unit 560, so the detector unit 560 may measure the thickness of the layer deposited on the substrate 100 in accordance with the monitor light 514. The detector unit 560 may express the measured thickness of the deposited material in terms of a tooling factor, thereby generating an “adjustment value.” The adjustment value may be transferred from the detector unit 560 to the layer thickness controller 400 of the deposition chamber 300, so that the flow rate and/or amount of the deposited material may be adjusted, e.g., via control of the evaporation source or the shutter 410. Consequently, the layer thickness deposited on the substrate 100 may be adjusted.

Even though the thickness measurement described above refers to an optical method via an ellipsometer, i.e., measurement of the polarization variation of incident and reflected light, other measurement methods are within the scope of the present invention. For example, the thickness of the layer on the substrate 100 may be measured by a mechanical method, e.g., via a diamond stylus having a radius of about 10 μm to about 50 μm, a microscopic method, e.g., via an electron microscope such as a scanning electron microscope (SEM) or an atomic force microscope, or other optical methods, e.g., a reflectometer, and so forth.

The layer on the substrate 100 may be deposited, measured, and adjusted in real time by the deposition chamber 300 and the measurement chamber 500. In this respect, it should be noted that “real time” does not refer to “instantaneously,” but to measurement and adjustment of the deposition material during the deposition process, as opposed to at the conclusion thereof. Accordingly, the thickness of the layer may be optimized during the deposition process.

Once the layer is formed, the substrate 100 may be transferred for further processing. For example, an encapsulation substrate, e.g., a polymer cap, a stainless steel cap, a cap with a moisture absorbent, and so forth, may be attached to the substrate 100 to form a sealed space, i.e., minimize contact of moisture and/or oxygen with the deposited layer, thereby reducing deterioration thereof. More specifically, the substrate 100 may be used as a lower substrate in an electroluminescent (EL) display device, so that the deposited layer may be a light emitting layer, e.g., an organic light emitting layer having a plurality of sub-layers, deposited and adjusted in the deposition apparatus 200 of the present invention.

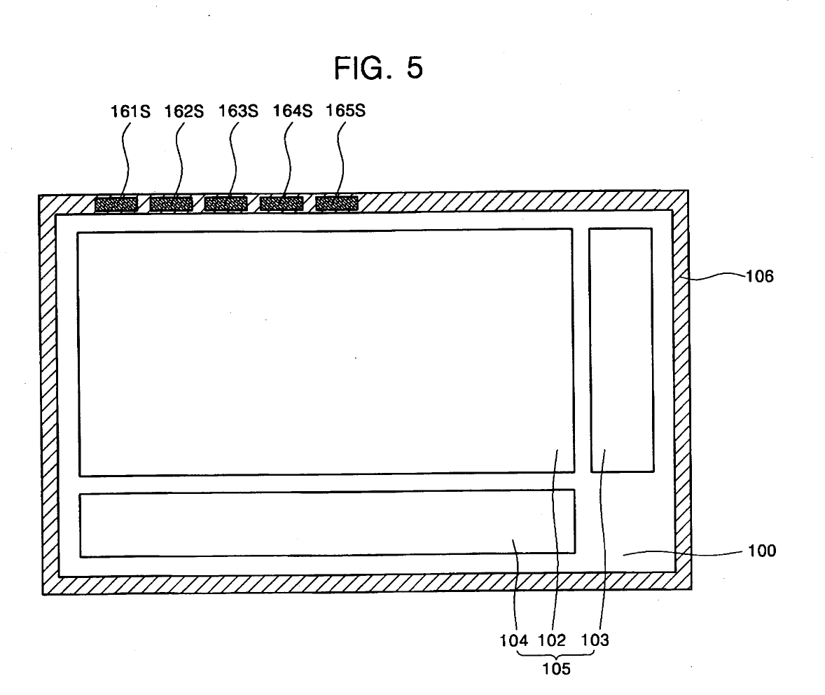

An exemplary embodiment of an EL display device having a light emitting layer formed in the deposition apparatus 200 according to the present invention will now be described more fully with reference to FIGS. 5-7. The EL display device may be formed on the substrate 100, so that a display region may be formed in the first predetermined region thereof. More specifically, as illustrated in FIG. 5, the EL display device may include a panel display portion 105 with a pixel region 102, a contact unit 103, and a pad unit 104 in the first predetermined region of the substrate 100. The pixel region 102 may include a plurality of pixel units, i.e., red (R), green (G) and/or blue (B) unit pixels, arranged in any suitable configuration. The contact unit 103 may connect an external signal to each unit pixel of the pixel region 102. The pad unit 104 may connect internal circuits, e.g., a data line circuit, a scan line circuit, and/or a common power source, to external sources. The substrate 100 may further include a panel peripheral portion 106 in the second predetermined region thereof. The panel peripheral portion 106 of the substrate 100 may surround the panel display portion 105, and may be a dummy region, i.e., an area including no direct display functions, surrounding the panel display portion 105.

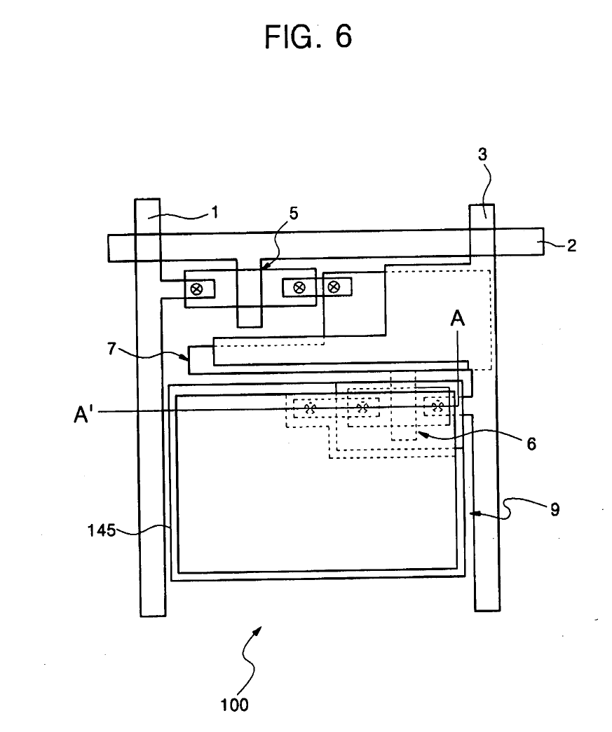

A single unit pixel in the pixel region 102 of the EL display device, as illustrated in FIG. 6, may include a scan line 2 in a first direction, a data line 1 in a second direction, e.g., the second direction may cross the first direction, and a common power line 3 in the second direction, i.e., in parallel to the data line 1. The scan line 2, data line 1, and common power line 3 may be insulated from one another, and they may define the single unit pixel, e.g., red (R), green (G), and/or blue (B), of the EL display device. A predetermined voltage may be applied independently to each of the scan line 2 and data line 1 to transmit signals to a light emitting diode 9.

In detail, a difference between the predetermined voltage, i.e., a signal, applied to the data line 1 and the scan line 2 may trigger charge accumulation in a capacitor 7, thereby activating a signal with respect to the accumulated charge to be input to a driving thin film transistor (TFT) 6 through a switching TFT 5. The signal input into the driving TFT 6 may be transmitted to the light emitting diode 9, thereby controlling light emission therefrom. The light emitting diode 9 may include a light emitting layer between electrodes, i.e., a lower electrode 145 and an upper electrode (not shown). If the light emitting layer is formed of an organic material, the light emitting diode 9 may be an organic light emitting diode.

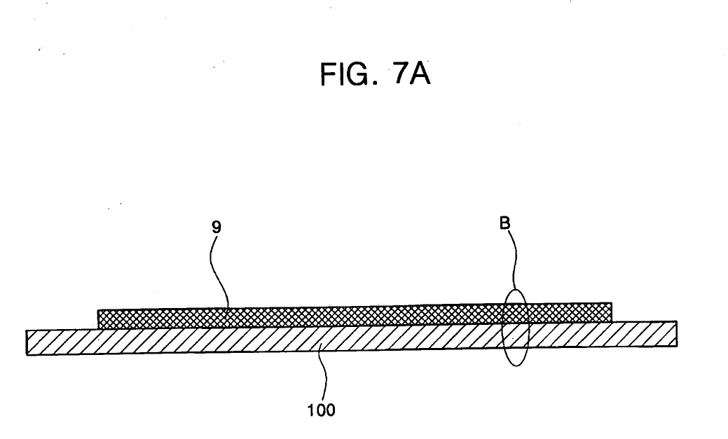

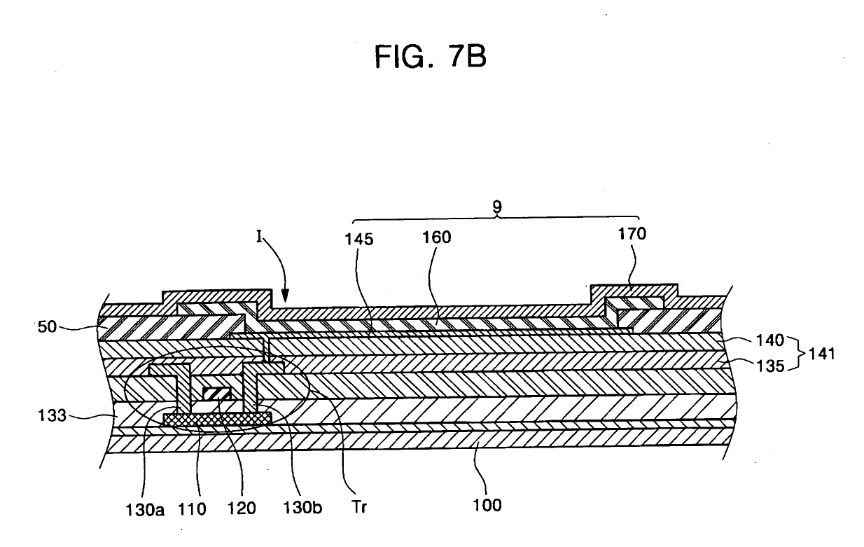

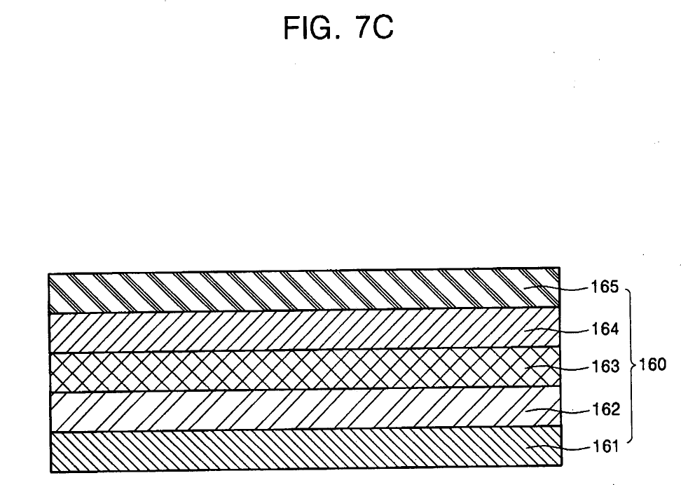

In further detail, as illustrated in FIGS. 7A-7B, the EL display device may include at least one TFT Tr and a plurality of functional layers, e.g., insulation layers, in addition to the light emitting diode 9. FIG. 7A illustrates a schematic cross-sectional view of a pixel region on the substrate of FIG. 5, and FIG. 7B a cross-sectional view along line AA′ in FIG. 6 and an enlarged view of area B of FIG. 7A.

As further illustrated in FIG. 7B, the substrate 100 may be formed of any suitable material, e.g., glass, synthetic resin, stainless steel, and so forth, followed by formation of the TFT Tr thereon. More specifically, a semiconductor layer 110 may be formed on the lower substrate 100, followed by sequential deposition of a gate insulating layer 133 and a gate electrode 120 on the semiconductor layer 110. A source electrode 130a and a drain electrode 130b may be formed through the gate insulating layer 133 to contact the semiconductor layer 110 in order to complete formation of the TFT Tr.

An insulating layer 141 may be formed on the TFT Tr of an inorganic material and/or an organic material. For example, the insulating layer 141 may include an inorganic protection layer 135, an organic planarization layer 140, or a combination thereof. Subsequently, the light emitting diode 9 may be formed.

More specifically, a conductive layer may be deposited on a portion of the insulating layer 141 to form a lower electrode 145. A via hole may be formed through the insulating layer 141, and a conductive material may be filled therein to connect the lower electrode 145 to the TFT Tr, e.g., the drain electrode 130b. The lower electrode 145 may be transparent and/or reflective. In particular, if the EL display device is a bottom emission type display, the lower electrode 145 may be transparent and an upper electrode 170 may be reflective. Alternatively, if the EL display device is a top emission structure, the upper electrode 170 may be transparent material and the lower electrode 145 may be reflective, thereby providing an increased area capable of transmitting light.

If the lower electrode 145 is transparent, it may be formed of, e.g., indium tin oxide (ITO), indium zinc oxide (IZO), tin oxide (TO), zinc oxide (ZnO), and so forth. If the lower electrode 145 is reflective, it may be formed of, e.g., silver (Ag), aluminum (Al), nickel (Ni), platinum (Pt), palladium (Pd), or a combination thereof, to reflect light emitted from an organic layer away from the lower substrate 100. The lower electrode 145 may include a double layer structure, e.g., a transparent layer and a reflective layer. The lower electrode 145 may be formed by a vapor phase deposition technique, e.g., sputtering and evaporation, an ion beam deposition, an electron beam deposition, a laser ablation technique, and so forth.

Then, an insulating material may be deposited and patterned on the lower electrode 145 to form a pixel definition layer 150. The pixel definition layer 150 may expose portions of an upper surface of the lower electrode 145, and may define a unit pixel region I. The pixel definition layer 150 may be formed of polyimide, a benzocyclobutene-based resin, a phenol resin, an acrylate, and so forth. Subsequently, a light emitting layer 160 and the upper electrode 170 may be sequentially deposited on the lower electrode 145.

In detail, as illustrated in FIG. 7C, the light emitting layer 160 may have a hole injection layer (HIL) 161, a hole transport layer (HTL) 162, an emission layer (EML) 163, an electron transport layer (ETL) 164, and an electron injection layer (EIL) 165. However, other structures of the light emitting layer 160, e.g., a structure without the ETL 164 and/or the EIL 165, a structure including a plurality of each layer, and so forth, are within the scope of the present invention.

The HIL 161 may be formed on the lower electrode 145, and may facilitate hole injection from the lower electrode 145 toward the EML 163. The HIL 161 may be formed of a low molecular material, e.g., copper phthalocyanine (CuPc); 4,4′,4″-Tris[N-(1-naphthyl)-N-phenyl-amino]-triphenylamine (TNATA); 4,4′,4″-Tri(N-carbazolyl)triphenylamine (TCTA); 1,3,5-tris[4-(diphenylamino)phenyl]benzene (TDAPB); 4,4′,4″-Tris(N,N-diphenylamino) triphenylamine (TDATA); and so forth, or a polymer material, e.g., polyailine (PANI) or poly(3,4)-ethylenedioxythiophene (PEDOT).

The HTL 162 may be formed on the HIL 161, and may facilitates hole transport from the HIL 161 to the EML 163. The HTL 162 may be formed of a low molecular material, e.g., N,N′-dinaphthyl-N,N′-diphenyl benzidine (NPD); N,N′-Bis-(3-methylphenyl)-N,N′-bis-(phenyl)-benzidine (TPD); 2,2′,7,7′-diphenyl-aminospiro-9,9′-bifluorene (s-TAD); 4,4′,4″-Tris(N-3-methylphenyl-N-phenyl-amino)-triphenylamine (MTDATA); and so forth, or a polymer material, e.g., poly(N-vinyl carbazole) (PVK).

The EML 163 may be formed on the HTL 162 of a photoluminescent material, e.g., a phosphorescent material or a fluorescent material. When the EML 163 is formed of a fluorescent material, it may include a host material, e.g., tris(8-quinolinolato) aluminum (Alq3); distyrylarylene (DSA); DSA derivatives; distyryl-benzene (DSB); DSB derivatives; 4,4′-bis(2,2′-diphenyl vinyl)-1,1′-biphenyl (DPVBi); DPVBi derivatives; 2,2′,7,7′-tetrakis(2,2-diphenylvinyl)spiro-9,9′-bifluorene (spiro-DPVBi); and spiro-sexyphenyl (spiro-6P), and a dopant, e.g., styrylamine-based material, pherylene-based material, and/or distyrylbiphenyl (DSBP) based material. On the other hand, when the EML 163 is formed of a phosphorescent material, it may include a host material, e.g., arylamine-based material, carbazole-based material, spiro-based material, and so forth. More specifically, the host material may be 4,4-N,N dicarbazole-biphenyl (CBP); CBP derivatives; N,N-dicarbazolyl-3,5-benzene (mCP); mCP derivatives; and spiro-series derivatives. In addition, the EML 163 may include a phosphorescent organometallic complex having a metal, e.g., iridium (Ir), platinum (Pt), terbium (Tb), europium (Eu), and so forth, as a dopant material. More specifically, the dopant may be tris(1-phenylquinoline) iridium (PQIr); bis(1-phenylquinoline)-acetylacetonate-iridium (PQIr)(acac); PQ2Ir(acac); bis(1-phenylisoquinoline) acetylacetonate iridium (PIQIr)(acac); and platinum-octaethylporphyrin (PtOEP).

The ETL 164 may be formed on the EML 163 to facilitate electron transport to the EML 163. The ETL 164 may be formed of a low molecule material, e.g., Alq3, BAlq, or bis(2-methyl-8-quinolinolato)-(triphenylsiloxy) aluminum(III) (SAlq), or of a polymer material, e.g., byphenyl-p-(t-butyl)phenyl-1,3,4-oxadiazole (PBD); TAZ; or spiro-PBD. The EIL 165 may be formed on the ETL 164, and may facilitate electron injection from the upper electrode 170 toward the EML 163. The EIL 165 may be formed of Alq3, lithium fluoride (LiF), Gallium (Ga) complex, or PBD.

The EML 163 may further include, e.g., a hole blocking layer (HBL) (not shown) on the EML 163 to minimize diffusion of excitons generated in the EML 163. The HBL may be formed of [(1,1′-biphenyl)-4-olato]bis(2-methyl-8-quinolinolato N1,08)aluminum (Balq); 2,9-dimethyl-4,7-diphenyl-1,10-phenanthroline (BCP); polymerized fluorocarbon (CF-X), (3-(4-Biphenylyl)-4-phenyl-5(4-tert-butylphenyl)-1,2,4-triazole) (TAZ); or spiro-TAZ. It should be noted, however, that the HBL may be omitted when the EML 163 is a fluorescent layer.

The light emitting layer 160, i.e., the HIL 161, HTL 162, EML 163, ETL 164, and/or EIL 165, may be formed by, e.g., vacuum deposition, spin coating, laser heat transfer, ink-jet technique, and so forth. When the light emitting layer 160 is formed by vacuum deposition, the deposition apparatus 200, as described above, may be employed to deposit uniform and continuous, i.e., substantially pinhole-free, layers on the substrate 100. The light emitting layer 160 may be deposited on a display panel portion 105 of the substrate 100, i.e., a “film layer” on the lower electrode 145 in the pixel unit 102, while a deposited material sample, as described previously with respect to FIG. 2, may be simultaneously deposited on the panel peripheral portion 106 of the substrate 100. For example, as illustrated in FIG. 5, while the HIL 161, HTL 162, EML 163, ETL 164, and EIL 165 are sequentially stacked on the lower electrode 145, corresponding deposited materials samples 161S, 162S, 163S, 164S, and 165S may be simultaneously deposited on the panel peripheral portion 106 to be coplanar and adjacent to each other. However, it should be noted that other configurations of deposited materials samples, e.g., on the display panel portion 105, are within the scope of the present invention.

According to embodiments of the present invention, the thickness of a layer deposited on a substrate may be measured in real time via a corresponding sample portion, so that a difference between the measured thickness value and a reference thickness value may be adjusted, thereby providing improved layer reproducibility. Further, material deposition and adjustment may be performed successively in an in-line automatic process, thereby enhancing deposition efficiency, production capability, and overall process yield. In addition, when the deposition material is an organic material, deterioration thereof may be reduced, thereby improving productivity and reducing production costs. Finally, use of the sample portion on a peripheral region of a substrate may facilitate thickness measurement and/or adjustment without damaging the substrate or elements thereon.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A deposition apparatus, comprising:
at least one deposition chamber having a source and a substrate holder, the source being configured to deposit a deposition material on a substrate on the substrate holder;
a measurement chamber electrically connected to the deposition chamber, the measurement chamber configured to measure in real time a thickness of the deposition material on the substrate; and
at least one layer thickness controller in contact with the deposition chamber.

2. The deposition apparatus as claimed in claim 1, wherein the layer thickness controller is electrically connected to the measurement chamber to receive the measured thickness, and is configured to control thickness adjustment thereof in accordance with the predetermined thickness.

3. The deposition apparatus as claimed in claim 2, wherein the layer thickness controller includes a shutter positioned between the evaporation source and the substrate holder.

4. The deposition apparatus according to claim 3, wherein the layer thickness controller is configured to open or close the shutter in response to a comparison between the predetermined thickness and the measured thickness.

5. The deposition apparatus as claimed in claim 1, wherein the measurement chamber further comprises:
a lower plate with first and second optical transmission holes therethrough;
a layer thickness monitoring unit configured to direct light toward the substrate; and
a detector unit configured to receive light reflected from the substrate.

6. The deposition apparatus as claimed in claim 5, wherein the detector unit is configured to determine the measured thickness and to transmit the measured thickness to the layer thickness controller.

7. The deposition apparatus as claimed in claim 6, wherein the detector unit includes an ellipsometer.

8. The deposition apparatus as claimed in claim 5, wherein the layer thickness monitoring unit is under the lower plate, and is configured to transmit light through the first optical transmission hole, and the detector unit is configured to receive light through the second optical transmission hole.

9. The deposition apparatus as claimed in claim 5, wherein the optical transmission holes include glass.

10. The deposition apparatus as claimed in claim 1, wherein the deposition apparatus includes a plurality of deposition chambers and a plurality of layer thickness controllers, each deposition chamber being electrically connected to the measurement chamber via a respective layer thickness controller.

11. A deposition method, comprising:
depositing a deposition material on a predetermined region of a substrate in a deposition chamber;
measuring in real time a thickness of the deposition material on the substrate in a measurement chamber;
comparing the measured thickness to a reference value to determine a tooling factor; and
controlling deposition of the deposition material on the substrate in real time with respect to the tooling factor.

12. The deposition method as claimed in claim 11, wherein controlling the thickness of the deposition material includes adjusting a flow rate and/or amount of the deposition material in the deposition chamber by a layer thickness controller.

13. The deposition method as claimed in claim 12, wherein controlling the flow rate and/or amount of the deposition material in the deposition chamber includes opening and/or closing a shutter by the layer thickness controller.

14. The deposition method as claimed in claim 11, wherein depositing the deposition material includes a bottom-up rotation deposition technique, a bottom-up deposition technique, a top-down deposition technique, and/or a vertical deposition technique.

15. The deposition method as claimed in claim 11, wherein depositing the deposition material includes depositing an organic material.

16. The deposition method as claimed in claim 11, wherein depositing the deposition material on a predetermined region of the substrate includes simultaneous deposition on a panel portion of the substrate and on a panel peripheral portion of the substrate.

17. The deposition method as claimed in claim 16, wherein measuring the thickness of the deposition material includes measuring the thickness in one or more of the panel peripheral portion of the substrate and/or the panel portion of the substrate.

18. The deposition method as claimed in claim 11, wherein measuring the thickness of the deposition material includes moving the substrate from the deposition chamber to the measurement chamber.

19. The deposition method as claimed in claim 11, wherein measuring the thickness of the deposition material includes measurement by an optical method, a mechanical method, and/or a microscopic method.

20. The deposition method as claimed in claim 19, wherein measuring the thickness of the deposition material includes measurement by an optical method, the optical method including measurement via an ellipsometer and/or a reflectometer.

21. The deposition method according to claim 19, wherein the thickness of the organic layer deposited in the predetermined region of the lower substrate is measured by measuring a polarization variation of incident light and reflected light transmitted through the measurement chamber.
